(19) United States
(12) Patent Application Publication
(10) Pub. No.: US 2007/0268668 A1
(43) Pub. Date: Nov. 22, 2007

(54) Kind of superconductive heat cooler package of vacuum used in computer CPU (Central Processing Unit)

(76) Inventors: I-Ming Lin, Walnut, CA (US); Fu-Hsing Hsieh, Taipei (TW)

Correspondence Address: I-Ming Lin, 350 Los Gatos Drive, Walnut, CA, 91789, US

(21) Appl. No.: 11/385,593

(22) Filed: May 19, 2006

(51) Int. Cl. H05K 7/20

(52) U.S. Cl. 361/697

(57) ABSTRACT

This is a type of superconductive vacuum heat cooler package used in computer CPU (Central Processing Unit). This invention dissipates heat through invented metal pipe materials and formula in single direction to achieve effective cooling result. This invention is to be utilized but not limited to computer Central Processing Unit.

A kind of Superconductive heat Cooler package of vacuum used in computer CPU (Central Processing Unit) includes:

1. Purpose: This is a type of heat dissipater equipment that is used on electronic CPU. This invention is to further raise the quality of heat dissipation on computer systems and other electronic devices by offering better design and cooling materials. CPU surface contacts the chassis mould group that connects to the superconductive heat pipes to form the ^{••}È shape package. The fan is located on the top part ^{••}È shape package dissipating heat toward the lower cooling plate of the package, thus lowering the temperature of the cooling plate and the heap pipes. The wind blows toward the heated CPU that contacts chassis mould group, causing the CPU to reach 160 Watt or above of excellent heat dissipation result.

2. The major parts include (Please look at FIG. 1): cooling plates mould (1), vacuum superconductive heat pipe (3), heat dissipater chassis mould group (2), end cover (5), cooling plate (11), separation buttons (12), pipe hole (13), fixed chassis (21), cover material (22), top cover (24) and heat pipe extension points (36).

3. Characteristic of the invention design: This invention utilizes a type of conductive pipe to transfer heat in selected shape; combing with the cooling plate, it could be utilized inside computer systems or other electronics device that requires a CPU.
1) Heat dissipation cooling plates are evenly distributed, and superconductive heat pipes are transferred through the middle to connect jointly together with the cooling plates. This causes the heat to travel through the heat pipes and dissipate among all the heating plate. The cooling fan will then blow on the plates, thus dissipating the heat.
2) At the end of the cooling plates and the tip of the heat pipes, a end cover was designed to not concentrate heat of the heat pipes at the end of the cooling plates. The user of end cover on the cooling plates is to dissipate extra heat and increase the power to dissolve heat. This design will help the cooling plates to increase its performance.
3) The top cover will make the end surface smooth. In this case, we do not need to adjust the heat pipes tip to the same height. This will cause fast and easy assemble that will result in saving manpower and man-hour.

4. Invention details: Please view FIGS. 1 to 5 as noted.
1) Vacuum superconductive heat pipes (3): please view FIGS. 1, 3 and 4. The heat pipes (3) go through the cooling plates (1) and ends at ending point (13). The heat pipes (3) will be exposed outside of cooling plate (11), forming heat pipe ends (36). (Copper or aluminum) metal tube (31), thin (copper or aluminum) metal net (32) and thin (copper or aluminum) metal balls (33) are melted to join together to develop the superconductive pipes (3). After vacuum treatment, many different liquid formulas are mixed to form the superconductive liquid (34) and are injected into heat pipes (3). The openings will then be sealed. This design utilizes the special performances from the many types of conductive liquids, causing the heat energy to easily convey hot to cold. This improves original single liquid design that needs to recycle through the heat pipes to reach the same performance. The superconductive mixed liquid (34) basic principle will form a distributed surface membrane (35) among the metal balls (33) and the metal net (32). The distributed surface membrane will move to push and shove each other, and conduct heat energy by the hot end to the cold end. The joint metal balls and metal net are close to the heart of the metal tube (31), causing the superconductive liquid (34) to move freely in the pipes due to no weight and no pressure. The success rate reaches 98%.
   1. Due to the formation of the surface membrane (35), the superconductive heat pipes (3) can be set at any angle; (it is not limited by the original design of single liquid in the heat pipe moving heat upward and cold air moves downward). This will increase usage. The item can be applied in various equipments and can be changed according to various heat dissipation packages.
      i. Due to the materials of the superconductive liquid can be changed by proportion and material, the temperature can be adjusted freely from −76° C.˜+1200° C.
      ii. Apply of the superconductive heat pipe (3); the heat dissipation distance can range freely by distance of 10 cm to 2 km. This functionality will achieve long distance application performance.
2) The cooling plates mould (1) are created with superconductive materials to create each individual cooling plate (11). The design utilizes the distance between separation buttons (12) to evenly distribute the cooling plates mould (1). Each cooling plate (11) will have a pipe hole (13) that allows superconductive heat pipes (3) to go through. A end cover (5) will then dissipate the heat from the end of the superconductive heat pipes (3), thus increases the performance of heat dissipation.
3) Heat conductor chassis mould group (2): this chassis mould group is the main conductor between the CPU (not shown in drawings) and the superconductive heat pipes (3). This conductor is the main relation that causes the CPU heat to spread speedily to the superconductive heat pipes (3). This contacting surface chassis mould group (2) utilizes high temperature and high pressure trimming to form its shape. The metal particles will be compressed to be more compact, and the space between the metal components will reduce. The content of air is reduced (air is the main factor that separates the heat conduction), the thermal resistance coefficient is reduced, and the heat conduction result improves. The chassis mould group (2) includes the support fixed chassis (21) and covering materials (22) and top cover (24). As shown in FIG. 2, the tube dents (23) are utilized to combine with superconductive heat pipes (3). The support bracket is used to secure the combination position between heat dissipation plates (1), superconductive heat pipes (3), and CPU; it will lock its position in the motherboard.
4) At the time of the combining the chassis mould group (2) and superconductive heat pipes (3); the chassis mould group will have a top roof plate (24). This top cover plate (24) benefits include:
   (a) The package will be leveled at the time of production; it does not need to be aliened, saving manpower sparingly.
   (b) It prevents chassis mould group heat energy from spreading, because superconductive heat pipes end will become heat conduction invalid area. The use of end plate will eliminate the useless area, thus increasing heat dissipation.
5) The cooling fan (4) is used for blowing the heat from cooling plates (1), superconductive heat pipes (3), and chassis mould group (2), thus getting the result of heat dissipation.

5. Figure Explanations
Cooling plates mould (1); Heat conductor chassis mould group (2); Superconductive heat pipes (3); Cooling fan (4); End cover (5); Cooling plate (11); Separation buttons (12); Pipe hole (13); Fixed chassis (21); Cover materials (22); Pipe dents (23); Top cover (24); Metal tube (31); Metal net (32); Metal balls (33); Superconductive liquid (34); Surface membrane (35); heat pipe ends (36).

6. Patent Materials Include
1) Heat dissipation package: CPU surface contacts the chassis mould group and the cooling plates mould that connects to the superconductive vacuum to form the ^{••}È shape package. This package is then combined with cooling fan to become a quality heat dissipation tool.
   a. Cooling plates mould
   b. Heat conductor chassis mould group
   c. At least one superconductive heat pipe
   d. Cooling fan
2) End cover: located at the end of cooling plates mould; this is where the superconductive heat pipes and the cooling plates combine. This will enhance heat dissipation at the end of the heat pipes.
3) The fixed chassis and covering materials: created with superconductive materials to form empty middle area to allow the connection of the superconductive heat pipes.
4) The top cover located near the fixed chassis: This is where the chassis mould group and the heat pipes connect. The cover will cover heat pipes end to allow better heat spread and thus enhancing heat dissipation.
5) At lease one pipe dent in chassis mould group: the dents are created to hold the heat pipes.
6) Superconductive heat pipes: After vacuum treatment, many different liquid formulas are mixed to form the superconductive liquid and are injected into heat pipes. The openings will then be sealed. The materials include:
   a. Copper or aluminum tube
   b. Copper or aluminum net
   c. Copper or aluminum balls
   d. Superconductive mixed liquid
7) Surface membrane in superconductive heat pipes: Copper or aluminum tube, thin copper or aluminum net and thin copper or aluminum balls are melted to join together to develop the conductive pipes. The surface of the melted materials will become the surface membrane.
8) The superconductive liquid formed with mixed formulas. The formulas are: H.0.Na, K2.Cr.O4, Ethanol, and H20 (water) . . . etc. The formulas were utilized according to lab measurements.
9) The superconductive liquid formula could be changed according to materials and change of measurements. Due to the materials of the superconductive liquid can be changed by proportion and material, the temperature can be adjusted freely from −76° C.˜+1200° C.

7. Drawing Figures:

A kind of Superconductive heat Cooler package of vacuum used in computer CPU (Central Processing Unit) includes:

### BACKGROUND OF THE INVENTION

The current CPU cooler in the market requires full current cycle of liquid flow to dissipate heat. Hot air would rise in the pipe and cool air would flow down. With our new invention of superconductive vacuum cooler, the heat is dissipated in one direction with our specialized metal pipes and cooling liquid formula. Our invention does not need the full cycle to dissipate heat. The heat flows in one direction (toward the cool end) and the cooler does not require cold air to flow down to the CPU. Through lab testing, this invention has proven to be very effective way of cooling electronic devices.

### 1. PURPOSE

This is a type of heat dissipater equipment that is used on electronic CPU. This invention is to further raise the quality of heat dissipation on computer systems and other electronic devices by offering better design and cooling materials. CPU surface contacts the chassis mould group that connects to the superconductive heat pipes to form the ^{••}È shape package. The fan is located on the top part ^{••}È shape package dissipating heat toward the lower cooling plate of the package, thus lowering the temperature of the cooling plate and the heap pipes. The wind blows toward the heated CPU that contacts chassis mould group, causing the CPU to reach 160 Watt or above of excellent heat dissipation result.

### 2. BRIEF DESCRIPTION OF THE DRAWINGS

The numbers in the figures are explained further in the specification.

FIG. 1—Disassembled superconductive vacuum cooler package view.

FIG. 2—Bracket and tube dents view of the package. This figure shows the disassembled inner Part of the metal bracket and tube.

FIG. 3—Cross-section pipe interior view. This figure shows the side cut view of the pipe interior.

FIG. 4—Mid-cut pipe interior view. This figure shows the center-cut view of the metal pipe interior.

FIG. 5—Assembled superconductive vacuum cooler package view.

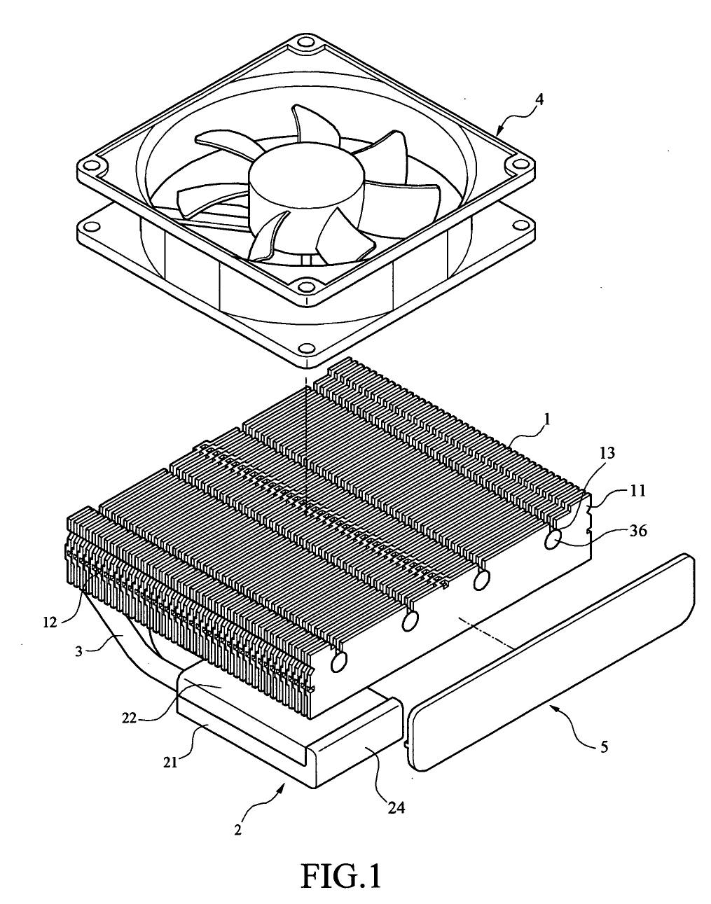

### 3. THE MAJOR PARTS INCLUDE (PLEASE LOOK AT FIG. 1)

Cooling plates mould (1), vacuum superconductive heat pipe (3), heat dissipater chassis mould group (2), end cover (5), cooling plate (11), separation buttons (12), pipe hole (13), fixed chassis (21), cover material (22), top cover (24) and heat pipe extension points (36).

### 4. CHARACTERISTIC OF THE INVENTION DESIGN

This invention utilizes a type of conductive pipe to transfer heat in selected shape; combing with the cooling plate, it could be utilized inside computer systems or other electronics device that requires a CPU.
1) Heat dissipation cooling plates are evenly distributed, and superconductive heat pipes are transferred through the middle to connect jointly together with the cooling plates. This causes the heat to travel through the heat pipes and dissipate among all the heating plate. The cooling fan will then blow on the plates, thus dissipating the heat.
2) At the end of the cooling plates and the tip of the heat pipes, a end cover was designed to not concentrate heat of the heat pipes at the end of the cooling plates. The user of end cover on the cooling plates is to dissipate extra heat and increase the power to dissolve heat. This design will help the cooling plates to increase its performance.
3) The top cover will make the end surface smooth. In this case, we do not need to adjust the heat pipes tip to the same height. This will cause fast and easy assemble that will result in saving manpower and man-hour.

### 5. INVENTION DETAILS

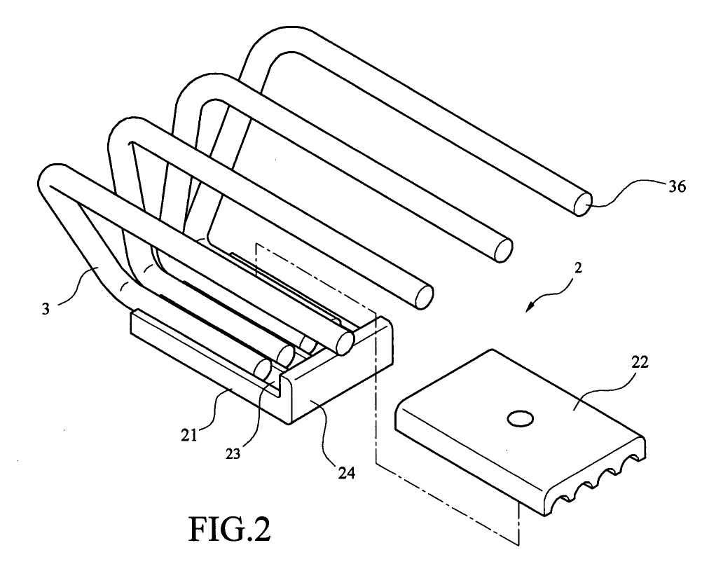

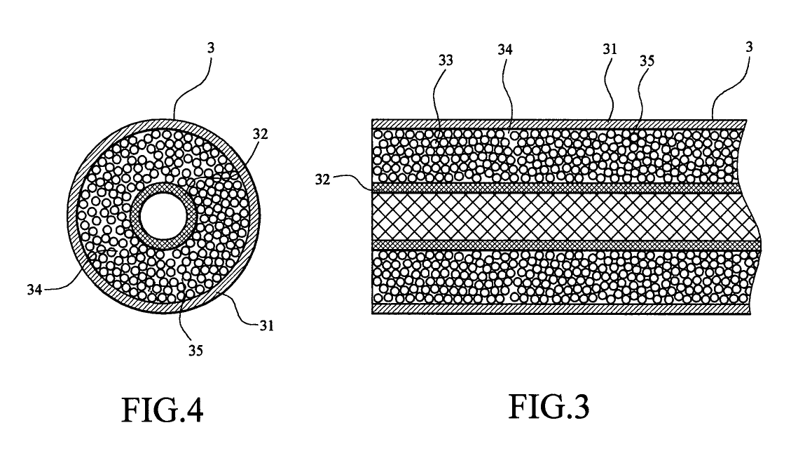

Please view FIGS. 1 to 5 as noted.
1) Vacuum superconductive heat pipes (3): please view FIGS. 1, 3 and 4. The heat pipes (3) go through the cooling plates (1) and ends at ending point (13). The heat pipes (3) will be exposed outside of cooling plate (11), forming heat pipe ends (36). (Copper or aluminum) metal tube (31), thin (copper or aluminum) metal net (32) and thin (copper or aluminum) metal balls (33) are melted to join together to develop the superconductive pipes (3). After vacuum treatment, many different liquid formulas are mixed to form the superconductive liquid (34) and are injected into heat pipes (3). The openings will then be sealed. This design utilizes the special performances from the many types of conductive liquids, causing the heat energy to easily convey hot to cold. This improves original single liquid design that needs to recycle through the heat pipes to reach the same performance. The superconductive mixed liquid (34) basic principle will form a distributed surface membrane (35) among the metal balls (33) and the metal net (32). The distributed surface membrane will move to push and shove each other, and conduct heat energy by the hot end to the cold end. The joint metal balls and metal net are close to the heart of the metal tube (31), causing the superconductive liquid (34) to move freely in the pipes due to no weight and no pressure. The success rate reaches 98%.
   1. Due to the formation of the surface membrane (35), the superconductive heat pipes (3) can be set at any angle; (it is not limited by the original design of single liquid in the heat pipe moving heat upward and cold air moves downward). This will increase usage. The item can be applied in various equipments and can be changed according to various heat dissipation packages.
      i. Due to the materials of the superconductive liquid can be changed by proportion and material, the temperature can be adjusted freely from −76° C.˜+1200° C.
      ii. Apply of the superconductive heat pipe (3); the heat dissipation distance can range freely by distance of 10 cm to 2 km. This functionality will achieve long distance application performance.
2) The cooling plates mould (1) are created with superconductive materials to create each individual cooling plate (11). The design utilizes the distance between separation buttons (12) to evenly distribute the cooling plates mould (1). Each cooling plate (11) will have a pipe hole (13) that allows superconductive heat pipes (3) to go through. An end cover (5) will then dissipate the heat from the end of the superconductive heat pipes (3), thus increases the performance of heat dissipation.
3) Heat conductor chassis mould group (2): this chassis mould group is the main conductor between the CPU (not shown in drawings) and the superconductive heat pipes (3). This conductor is the main relation that causes the CPU heat to spread speedily to the superconductive heat pipes (3). This contacting surface chassis mould group (2) utilizes high temperature and high pressure trimming to form its shape. The metal particles will be compressed to be more compact, and the space between the metal components will reduce. The content of air is reduced (air is the main factor that separates the heat conduction), the thermal resistance coefficient is reduced, and the heat conduction result improves. The chassis mould group (2) includes the support fixed chassis (21) and covering materials (22) and top cover (24). As shown in FIG. 2, the tube dents (23) are utilized to combine with superconductive heat pipes (3). The support bracket is used to secure the combination position between heat dissipation plates (1), superconductive heat pipes (3), and CPU; it will lock its position in the motherboard.
4) At the time of the combining the chassis mould group (2) and superconductive heat pipes (3); the chassis mould group will have a top roof plate (24). This top cover plate (24) benefits include:
   (a) The package will be leveled at the time of production; it does not need to be aliened, saving manpower sparingly.
   (b) It prevents chassis mould group heat energy from spreading, because superconductive heat pipes end will become heat conduction invalid area. The use of end plate will eliminate the useless area, thus increasing heat dissipation.
5) The cooling fan (4) is used for blowing the heat from cooling plates (1), superconductive heat pipes (3), and chassis mould group (2), thus getting the result of heat dissipation.

### 6. FIGURE EXPLANATIONS

Cooling plates mould (1); Heat conductor chassis mould group (2); Superconductive heat pipes (3); Cooling fan (4); End cover (5); Cooling plate (11); Separation buttons (12); Pipe hole (13); Fixed chassis (21); Cover materials (22); Pipe dents (23); Top cover (24); Metal tube (31); Metal net (32); Metal balls (33); Superconductive liquid (34); Surface membrane (35); heat pipe ends (36).

### 7. PATENT MATERIALS INCLUDE

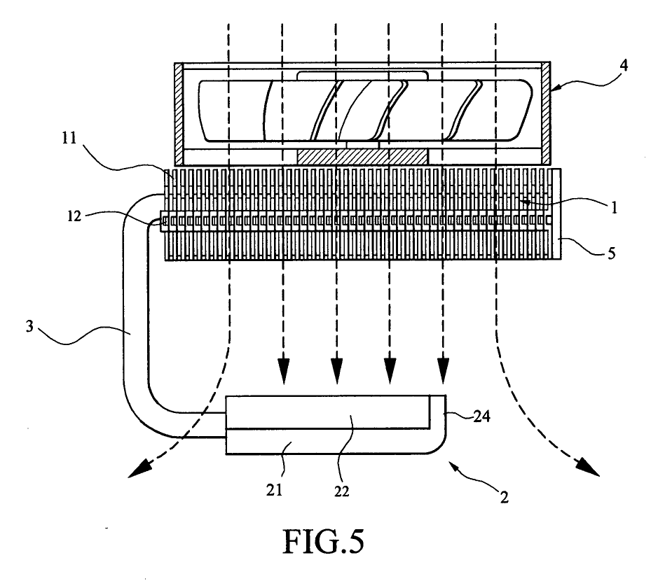

1) Heat dissipation package: CPU surface contacts the chassis mould group and the cooling plates mould that connects to the superconductive vacuum to form the ^{••}È shape package. This package is then combined with cooling fan to become a quality heat dissipation tool (please see FIG. 5).
   a. Cooling plates mould
   b. Heat conductor chassis mould group
   c. At least one superconductive heat pipe
   d. Cooling fan
2) End cover: located at the end of cooling plates mould; this is where the superconductive heat pipes and the cooling plates combine. This will enhance heat dissipation at the end of the heat pipes.
3) The fixed chassis and covering materials: created with superconductive materials to form empty middle area to allow the connection of the superconductive heat pipes.
4) The top cover located near the fixed chassis: This is where the chassis mould group and the heat pipes connect. The cover will cover heat pipes end to allow better heat spread and thus enhancing heat dissipation.
5) At lease one pipe dent in chassis mould group: the dents are created to hold the heat pipes.
6) Superconductive heat pipes: After vacuum treatment, many different liquid formulas are mixed to form the superconductive liquid and are injected into heat pipes. The openings will then be sealed. The materials include:
   e. Copper or aluminum tube
   f. Copper or aluminum net
   g. Copper or aluminum balls
   h. Superconductive mixed liquid
7) Surface membrane in superconductive heat pipes: Copper or aluminum tube, thin copper or aluminum net and thin copper or aluminum balls are melted to join together to develop the conductive pipes. The surface of the melted materials will become the surface membrane.
8) The superconductive liquid formed with mixed formulas. The formulas are: H.0.Na, K2.Cr.O4, Ethanol, H20 (water) and etc . . . . The formulas were utilized according to lab measurements.
9) The superconductive liquid formula could be changed according to materials and change of measurements. Due to the materials of the superconductive liquid can be changed by proportion and material, the temperature can be adjusted freely from −76° C.˜+1200° C.

1. A method of dissipating heat through invented metal pipe and liquid formula in single direction. The heat is pushed toward the cold end in single direction and the cool air does not need to flow down to the computer CPU to carry more heat. The new invention does not need the full heat flow cycle to dissipate heat.
A method of claim involves testing the metal pipes with various temperature and high-end CPU in the world.
A method of claim involves experimenting with different formula to allow fast dissipation result.

2. A method of dissipating heat without any angle restriction of cooler package. The superconductive vacuum cooler can be placed in any angle without being effected by outside environment. This is due to heat will dissipate toward cool end (location of the fan) in single direction only.
A method of claim involves testing this package on computer CPU in various angle. This results in this package can be utilized in various electronic products not limited to computer CPU.
